(19) United States
(12) Patent Application Publication
(10) Pub. No.: US 2013/0295283 A1
(43) Pub. Date: Nov. 7, 2013

(54) CHEMICAL VAPOR DEPOSITION APPARATUS WITH MULTIPLE INLETS FOR CONTROLLING FILM THICKNESS AND UNIFORMITY

(71) Applicant: Heng Liu, Sunnyvale, CA (US)

(72) Inventor: Heng Liu, Sunnyvale, CA (US)

(73) Assignee: PINECONE MATERIAL INC., Taipei City (TW)

(21) Appl. No.: 13/465,075

(22) Filed: May 7, 2012

(51) Int. Cl. C23C 16/455; C23C 16/06; C23C 16/458

(52) U.S. Cl. 427/255.28; 118/715; 118/730

(57) ABSTRACT

A chemical vapor deposition system includes first inlets that are located in a gas injector. Second inlets are also located in the gas injector. A first piping branch provides a gas to the first inlets and/or the second inlets. The first piping branch provides the gas at a first flow rate to the first inlets and/or at a second flow rate to the second inlets. A second piping branch provides a gas to the first inlets and/or the second inlets. The second piping branch provides the gas at at least a third flow rate to the first inlets and/or the second inlets.

### RELATED PATENT

This patent application is related to copending U.S. patent application Ser. No. 13/162,416 filed on Jun. 16, 2011 which is incorporated by reference as if fully set forth herein.

### BACKGROUND

1. Field of the Invention

The present invention relates to methods and systems for forming semiconductor materials. More particularly, the invention relates to a chemical vapor deposition system and related methods for forming semiconductor materials. Merely by way of example, the invention has been applied to forming Group-III nitride materials but it would be recognized that the invention has a much broader range of applicability.

2. Description of Related Art

Metal-organic chemical vapor deposition (MOCVD) has been widely used for fabricating epitaxial layers of Group-III/Group-V materials (e.g., Group-III nitride materials) such as aluminum nitride, gallium nitride, and/or indium nitride. MOCVD apparatus are often easy to use and suitable for mass production. Usually, one or more Group-III metal organic (MO) gases and one or more Group-V gases are used to form the Group-III nitride materials. Group-III MO gases may include, for example, TMGa (e.g., trimethylgallium ((CH₃)₃Ga)), TEGa (e.g., triethylgallium ((C₂H₆)₃Ga)), TMAl (e.g., trimethylaluminum ((CH₃)₃Al)), and/or TMIn (e.g., trimethylindium ((CH₃)₃In)). Group-V gases may include, for example, ammonia (e.g., NH₃).

Epitaxial layers made by MOCVD are used to make light emitting diodes (LEDs). The quality of LEDs formed using MOCVD are affected by various factors such as, but not limited to, flow stability or uniformity inside the reaction chamber, flow uniformity across the substrate surfaces, and/or accuracy of temperature control. Variations in these factors may adversely affect the quality of epitaxial layers formed using MOCVD and, hence, the quality of LEDs produced using MOCVD.

MOCVD apparatus may be used to grow epitaxial structures such as epitaxial stacked layer structures that include heterojunction interfaces between different Group-III nitride materials (e.g., an interface between GaN and InGaN). For stacked layer structures, the composition must change sharply at the heterojunction interface. Conventional vapor deposition apparatus in which semiconductor crystal layers (for example, Group-III nitride materials) are vapor-grown by MOCVD may not include piping systems through which a group III or group V element source passes constantly.

In order to solve the problems with piping systems in the conventional vapor deposition apparatus, vent/run piping systems have been developed. Vent/run piping systems include a mechanism that enables constant flow of a source gas and instantaneous switching of the gas supplied to a vapor deposition region (see, for example, J. Crystal Growth, vol. 68 (1984), pp. 412-421 and 466-473; and “III-V ZOKU KAGOBUTSU HANDOTAI,” edited by Isamu Akasaki, published on May 20, 1994 by Baifukan, 1st edition, pp. 68-70, which is incorporated by reference as if fully set forth herein). In a vent/run piping system, a vent line (exhaust line) is provided to constantly supply a source gas to the outside of a vapor deposition region in advance to maintain a constant flow rate of the gas, regardless of whether or not the gas is necessary for vapor-growth of the intended crystal layers. A run line (source supply line) is connected directly to the vapor deposition region, and is provided for supplying the source gas necessary to the region for vapor-growth of the intended crystal layers. The flow of the source gas is switched from the vent line to the run line. The vent/run system includes the vent line through which the source gas passes constantly unlike conventional piping systems that contain only a source supply line.

During MOCVD of Group-III nitride materials, the ammonia gas often is used to supply nitrogen atoms. The dissociation efficiency of ammonia, however, depends on temperature with a higher temperature of the ammonia providing higher dissociation efficiency. For example, at 800° C., the dissociation efficiency of ammonia is only about 10%, whereas at 900° C., the dissociation efficiency of ammonia is about 20%. In contrast, the Group-III MO gases usually start to dissociate at a lower temperatures (for example, between about 300° C. and about 400° C.).

After the ammonia gas and the Group-III MO gas disassociate, the solid Group-III nitride materials may be formed. It is often important to match the heating of the gases and the transport of the gases so that the Group-III nitride materials do not form too early or too late. For example, the Group-III nitride materials should not be deposited on surfaces of various components of the MOCVD system or discharged out of the MOCVD system with other byproducts. Instead, the Group-III nitride materials are preferably formed on substrate surfaces (e.g., wafer surfaces) in order to lower cleaning costs and reduce consumption of reaction materials.

Additionally, for different Group-III nitride materials (e.g., gallium nitride and indium nitride), their respective growth conditions to form epitaxial layers may differ significantly. For example, the growth temperature for gallium nitride is desired to be above 1000° C. while the growth temperature for indium nitride is desired to be below 650° C. As another example, to form indium-gallium nitride, the growth temperature is limited by the lower desirable temperature for indium nitride in order to reduce dissociation between indium and nitrogen atoms. But at the low growth temperature, a large amount of ammonia often needs to be supplied in order to provide sufficient nitrogen atoms for the chemical reactions. Usually, the nitrogen consumption for growing indium nitride is several times more than the nitrogen consumption for growing gallium nitride or aluminum nitride. The supply of nitrogen atoms can also be enhanced by raising the partial pressure of ammonia. Such high partial pressure, however, can make the epitaxial layers less uniform and increase fabrication costs.

U.S. patent application Ser. No. 13/162,416 to Liu et al. (“Pat. Appl. No. '416”), which is incorporated by reference as if fully set forth herein, provides an improved MOCVD reaction system and associated method for forming Group-III nitride materials. Many benefits are provided in Pat. Appl. No. '416 over conventional techniques. Certain embodiments of Pat. Appl. No. '416 provide a reaction system for chemical vapor deposition (CVD) with reduced consumption of one or more gas materials. For example, using the reaction system of Pat. Appl. No. '416, metal-organic chemical vapor deposition (MOCVD) is performed with reduced consumption of ammonia. Some embodiments of Pat. Appl. No. '416 provide a reaction system for Group-III nitride formation (e.g., aluminum nitride, gallium nitride, and/or indium nitride) that can reduce costs and improve performance of the MOCVD process.

### SUMMARY

In certain embodiments, a chemical vapor deposition system includes a gas injector, one or more first inlets and one or more second inlets. The first inlets are located in the gas injector. The second inlets are also located in the gas injector. A first piping branch is coupled to the first inlets and/or the second inlets. The first piping branch provides at least one gas to the first inlets and/or the second inlets during use. The first piping branch provides the at least one gas at a first flow rate to the first inlets and/or at a second flow rate to the second inlets. A second piping branch is coupled to the first inlets and/or the second inlets. The second piping branch provides at least one gas to the first inlets and/or the second inlets during use. The second piping branch provides the at least one gas at at least a third flow rate to the first inlets and/or the second inlets.

In certain embodiments, a method for chemical vapor deposition includes providing a system for forming one or more layers of material on one or more substrates. The system includes a gas injector, one or more first inlets, and one or more second inlets. The first inlets are located in the gas injector. The second inlets are also located in the gas injector. At least one gas is provided from a first piping branch at a first flow rate to the first inlets and/or at a second flow rate to the second inlets. At least one additional gas is provided from a second piping branch at at least a third flow rate to the first inlets and/or the second inlets.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1 depicts an embodiment of a chemical vapor deposition system.

FIG. 1A depicts an alternative embodiment of a chemical vapor deposition system.

FIG. 2 depicts an example of a method for adjusting one or more distributions of one or more growth rates for one or more Group-III nitride materials using a chemical vapor deposition system.

FIG. 3 shows an example of the growth rate of GaN as a function of radial distance with rotation around a susceptor axis but without rotation around a holder axis.

FIG. 4 shows an example of the growth rate of GaN as a function of radial distance with rotation around a susceptor axis and also with rotation around a holder axis.

FIG. 5 depicts an embodiment of a single gas source vent/run piping system.

FIG. 6 depicts an embodiment of a dual gas source vent/run piping system.

FIG. 7 depicts an embodiment of a dual gas source vent/run piping system with two piping branches.

FIG. 8 depicts an alternative embodiment of a dual gas source vent/run piping system with two piping branches.

FIG. 9 depicts yet another embodiment of a dual gas source vent/run piping system with two piping branches.

FIG. 10 depicts yet another alternative embodiment of a dual gas source vent/run piping system with two piping branches.

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

In the context of this patent, the term “coupled” means either a direct connection or an indirect connection (e.g., one or more intervening connections) between one or more objects or components. While embodiments described herein are directed to a chemical vapor deposition system and related method for forming Group-III/Group-V materials, it is to be understood that the forming of Group-III/Group-V materials is merely provided as example and that it would be recognized that the chemical vapor deposition system and method described herein have a much broader range of applicability. For example, the chemical vapor deposition system and method may be applied to growth of Group-II/Group-VI materials.

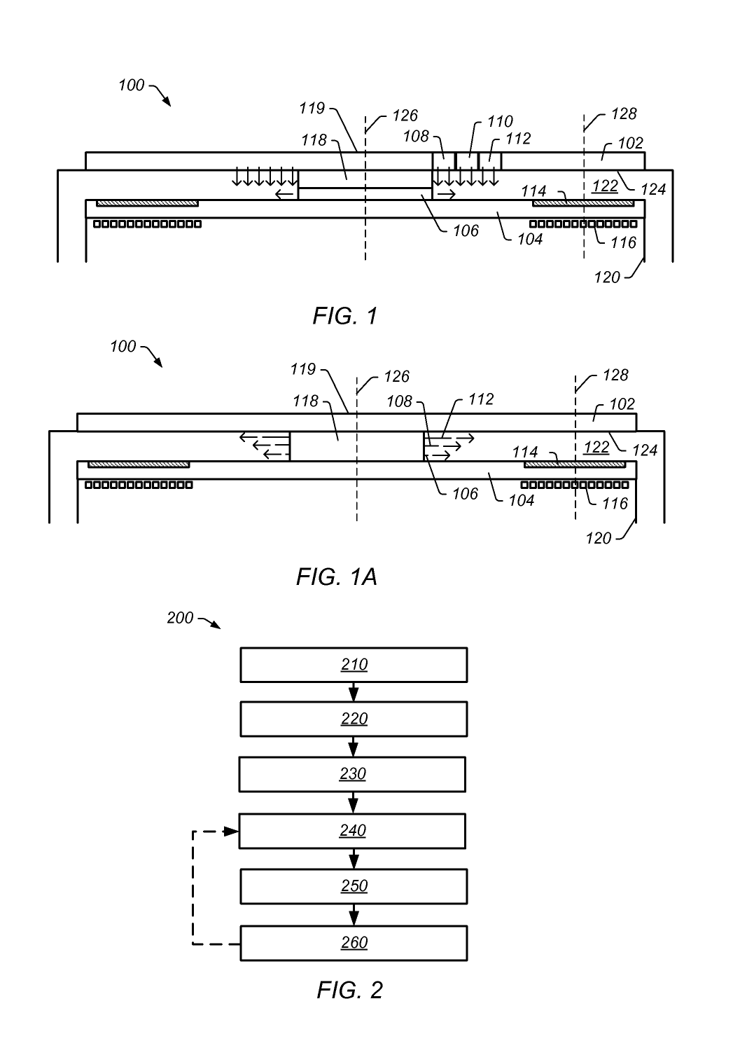

FIG. 1 depicts an embodiment of chemical vapor deposition system 100. Chemical vapor deposition system 100, as shown in FIG. 1, may be described in further detail in U.S. patent application Ser. No. 13/162,416 to Liu et al. (“Pat. Appl. No. '416”). FIG. 1A depicts an alternative embodiment of chemical vapor deposition system 100. As shown in FIGS. 1 and 1A, chemical vapor deposition system 100 includes plane component 102, susceptor 104, inlets 106, 108, 110, 112, one or more substrate holders 114, one or more heating devices 116, central component 118, and outlet 120. In certain embodiments, plane component 102 and central component 118 together form gas injector 119.

In certain embodiments, gas injector 119 (e.g., central component 118 and plane component 102), susceptor 104, and one or more substrate holders 114 (e.g., located on the susceptor) form reaction chamber 122 with the inlets 106, 108, 110, 112 and outlet 120 for the reaction gases. Outlet 120 may be an exhaust gas outlet for reaction chamber 122. One or more substrate holders 114 may each be used to carry one or more substrates (e.g., one or more wafers).

In certain embodiments, chemical vapor deposition system 100 includes inlet 106 located in central component 118. Inlet 106 may provide one or more gases (e.g., source gases) in a direction that is substantially parallel to surface 124 of plane component 102. For example, the gases may flow (e.g., flow upward or flow downward) into reaction chamber 122 near the center of the reaction chamber and then flow through inlet 106 outward radially, away from the center of the reaction chamber. In certain embodiments, inlet 106 provides group-V or group-VI source gases to reaction chamber 122. For example, inlet 106 may provide NH₃ (ammonia) to reaction chamber 122.

In some embodiments, as shown in FIG. 1, inlets 108, 112 are located within plane component 102 and provide one or more gases (e.g., source gases) in a direction that is substantially perpendicular to surface 124. In some embodiments, as shown in FIG. 1A, inlets 108, 112 are located in central component 118 and provide one or more gases (e.g., source gases) in a direction that is substantially parallel to surface 124. In certain embodiments, as shown in FIGS. 1 and 1A, inlet 108 and inlet 112 provide group-III or group-II source gases to reaction chamber 122. For example, inlet 108 and inlet 112 may provide metal organic source gases such as TMGa, TEGa, TMAl, or TMIn. In some embodiments, the source gases are combined with a carrier gas such as N₂ or H₂. For example, inlet 110, shown in FIG. 1, may provide carrier gas to reaction chamber 122 (e.g., N₂, H₂, or NH₃).

In certain embodiments, as shown in FIGS. 1 and 1A, susceptor 104 rotates around susceptor axis 126 (e.g., a central axis) and each of the one or more substrate holders 114 rotates around a corresponding holder axis 128. In some embodiments, one or more substrate holders 114 rotate with susceptor 104 around susceptor axis 126 and also rotate around their corresponding holder axes 128. For example, one or more substrates on the same substrate holder 114 can rotate around the same holder axis 128. In certain embodiments, inlets 106, 108, 110, 112 and outlet 120 each have a circular configuration around susceptor axis 126. Inlets 106, 108, 110, 112 are located upstream of substrate holder 114 such that the inlets are not covering any portion of the substrates on the substrate holder.

In certain embodiments, the distance between plane component 102 and substrates on substrate holder 114 is 20 mm or less (e.g., 15 mm or less). Maintaining such distance between plane component 102 and the substrates provides high epitaxial growth pressures in reaction chamber 122 (e.g., pressures larger than 500 torr).

As shown in FIGS. 1 and 1A, one or more heating devices 116 are located under one or more substrate holders 114. In certain embodiments, one or more heating devices 116 extend toward the center of reaction chamber 122 beyond the inside edge of one or more substrate holders 114. Extending heating devices 116 beyond the inside edge of substrate holder 114 may preheat the gases provided from inlets 106, 108, 110, 112 before the gases reach the substrate holder.

Using chemical vapor deposition system 100 shown in FIGS. 1 and 1A, flow rates of gases provided through inlets 108 and 112 may be adjusted to provide uniform film thicknesses (e.g., GaN film thickness) on substrates on substrate holder 114. FIG. 2 depicts an example of method 200 for adjusting one or more distributions of one or more growth rates for one or more Group-III nitride materials using chemical vapor deposition system 100. Method 200 may include process 210 for selecting flow rates of one or more Group-V gases and one or more carrier gases for inlets, process 220 for determining one or more distributions of growth rates for one or more Group-III nitride materials if one or more metal organic gases flow through only inlet 108, process 230 for determining one or more distributions of growth rates for one or more Group-III nitride materials if one or more metal organic gases flow through only inlet 112, process 240 for selecting a distribution of one or more metal organic gases between inlets 108 and 112, process 250 for determining one or more distributions of growth rates for one or more Group-III nitride materials by superposition, and process 260 for assessing the one or more distributions of growth rates for one or more Group-III nitride materials.

Although FIG. 2 shows a selected group of processes for method 200, it is to be understood that there can be many alternatives, modifications, and variations to the method depicted. For example, some of the processes may be modified, expanded, and/or combined, some processes may be skipped or deleted, and other processes may be inserted to those described herein.

At process 210, the flow rates of one or more Group-V gases and one or more carrier gases are selected for the inlets 106, 108, 110, 112. For example, the Group-V gases may include NH₃ and the carrier gases may include H₂ and/or N₂. In some embodiments, at process 210, the total flow rate of the one or more metal organic gases (e.g., TMGa) is also determined. In some embodiments, at process 210, the pressure within reaction chamber 122, the temperature of heating devices 116, and the temperature of plane component 102 are also determined

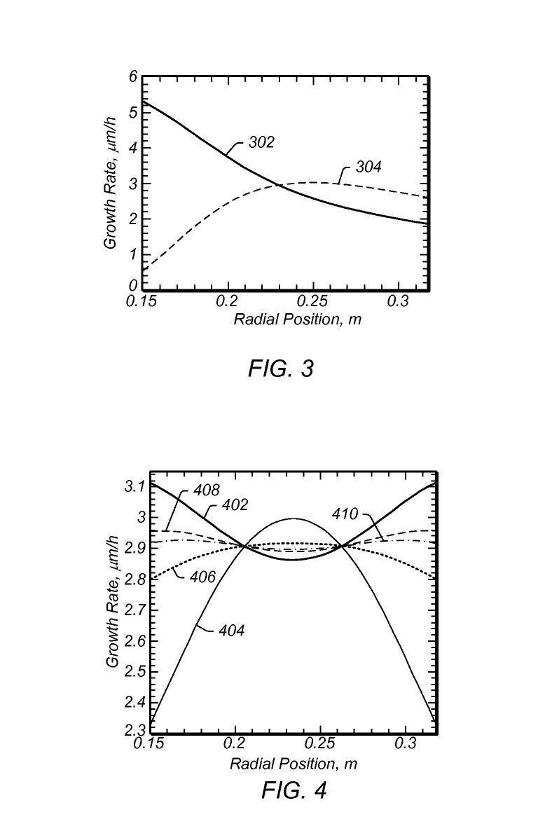

At process 220, one or more distributions of growth rates for the one or more Group-III nitride materials are determined if the one or more metal organic gases flow only through inlet 108. FIG. 3 shows an example of the growth rate of GaN as a function of radial distance with rotation around susceptor axis 126 but without rotation around holder axis 128. FIG. 4 shows an example of the growth rate of GaN as a function of radial distance with rotation around susceptor axis 126 and also with rotation around holder axis 128. FIGS. 3 and 4 present data as one example of optimized processing conditions that may be used for form GaN films. It is to be understood that the optimized conditions will vary based on one or more parameters such as, but not limited to, substrate temperature, reaction chamber pressure, carrier gas type as well as reaction chamber dimensions and reaction chamber design.

Curve 302 in FIG. 3 and curve 402 in FIG. 4 depict the growth rate distribution profiles of GaN with metal organic gases flowing only through inlet 108 in the respective figures. At process 230, one or more distributions of growth rates for the one or more Group-III nitride materials are determined if the one or more metal organic gases flow only through inlet 112. Curve 304 in FIG. 3 and curve 404 in FIG. 4 depict the growth rate distribution profiles of GaN with metal organic gases flowing only through inlet 112 in the respective figures.

At process 240, a distribution of the one or more metal organic gases between inlets 108 and 112 is selected. For example, the flow rate of the TMGa gas is allocated to inlets 108 and 112 at various ratios (e.g., X % for inlet 108 and Y % for inlet 112) with the total flow rates unchanged (e.g., X %+Y %=100%).

At process 250, for the selected distribution of the one or more metal organic gases, one or more distributions of growth rates for the one or more Group-III nitride materials are determined by superposition. For example, the growth rate of GaN is determined by adding X % multiplied by the growth rate previously determined at process 220 and Y % multiplied by the growth rate previously determined at process 230.

At process 260, the one or more distributions of growth rates for the selected distribution of the one or more metal organic gases are assessed to determine whether the one or more distributions of growth rates satisfy one or more predetermined conditions (e.g., in terms of uniformity). For example, if the one or more predetermined conditions are not satisfied, the method returns to process 240. If the one or more predetermined conditions are satisfied, chemical vapor deposition is performed to form the one or more Group-III nitride materials (e.g., using chemical vapor deposition system 100).

As shown in FIG. 4, curve 406 depicts the growth rate distribution profile of GaN with 60% for inlet 108 and 40% for inlet 112; curve 408 depicts the growth rate distribution profile of GaN with 80% for inlet 108 and 20% for inlet 112; and curve 410 depicts the growth rate distribution profile of GaN with 75% for inlet 108 and 25% for inlet 112. As shown by curve 406, insufficient supply of TMGa through inlet 108 results in a convex profile for the growth rate and the growth rate profile is unsatisfactory. As shown by curve 408, insufficient supply of TMGa through inlet 112 results in a concave profile for the growth rate and the growth rate profile is unsatisfactory. As shown by curve 410, a substantially uniform distribution of growth rate for GaN may be achieved for X % equal to 75% and Y % equal to 25% and the growth rate is satisfactory.

In order to achieve a substantially uniform distribution of growth rate (e.g., as shown by curve 410), it is important that curve 402 is concave and the curve 404 is convex as shown in FIG. 4. For example, if the peak of the growth rate of GaN with rotation around susceptor axis 126 but without rotation around holder axis 128 (as shown in FIG. 3) lies outside substrate holder 114 (e.g., as shown by curve 302 in FIG. 4), then curve 402 is concave.

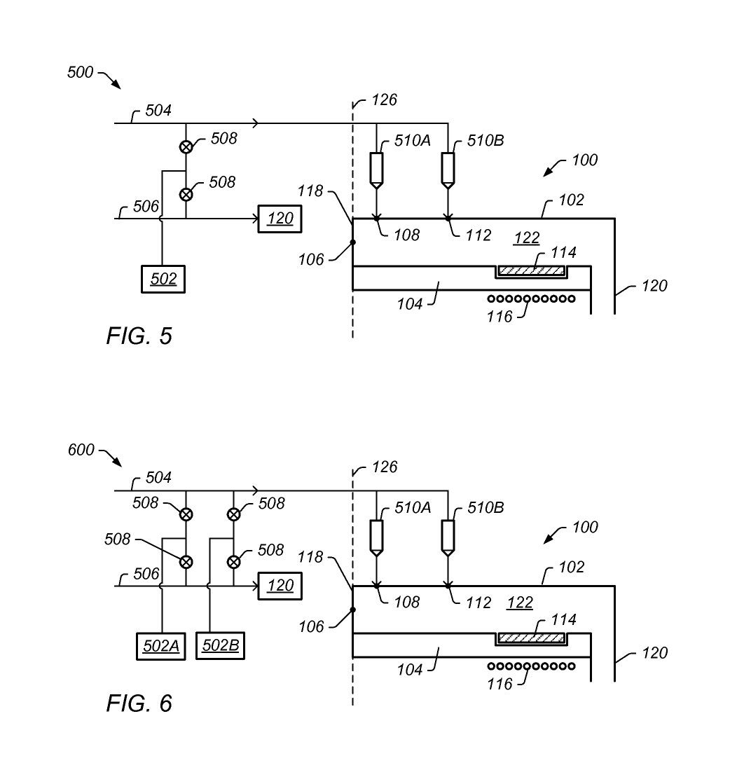

FIGS. 3 and 4 present examples of data for optimized conditions for TMGa as the source gas. It is to be understood that the methods and processes described herein and in Pat. Appl. No. '416 may be used find optimized conditions for other source gases. For example, growth conditions using TMIn may be optimized at 50% for inlet 108 and 50% for inlet 112. It is also noted that FIGS. 3 and 4 present data for optimized conditions for using vent/run piping systems using a single gas source (e.g., either TMGa or TMIn but not in combination). FIG. 5 depicts an embodiment of a single gas source vent/run piping system. Piping system 500 is coupled to chemical vapor deposition system 100. For simplicity in the drawings, only certain aspects of chemical vapor deposition system 100 are shown in FIG. 5 and other figures depicting piping systems. It is to be understood that chemical vapor deposition system 100, as shown in FIG. 5, may include other elements previously described or suggested and that the location and/or orientation of inlets (e.g., inlets 108, 112) may be as described and suggested for the embodiments of chemical vapor deposition system 100 depicted in either FIG. 1 or FIG. 1A (e.g., inlets 108, 112 may be in either plane component 102 or central component 118).

Piping system 500 includes gas source 502 coupled to both run line 504 and vent line 506. In certain embodiments, gas source 502 provides group-III metal organic gas. For example, gas source 502 may provide TMGa, TEGa, TMAl, or TMIn gas. In some embodiments, a carrier gas supply is coupled to gas source 502, run line 504, and/or vent line 506 to provide carrier gas along with the metal organic gas.

Valves 508 may be located between gas source 502 and run line 504 and/or vent line 506 for isolation between the run/vent lines. Vent line 506 provides gas from gas source 502 to outlet 120 (e.g., gas exhaust for chemical vapor deposition system 100). Run line 504 is coupled to both inlet 108 and inlet 112. Flow controllers 510A, 510B may couple run line 504 to inlets 108, 112. Flow controllers 510A, 510B may be, for example, mass flow controllers or other devices to control the flow rate of gas from gas source 502 into inlets 108, 112. Flow controllers 510A, 510B may be used to control the ratio of source gas provided to inlets 108, 112 (e.g., X % for inlet 108 and Y % for inlet 112).

While FIGS. 3 and 4 present data for optimized conditions for using vent/run piping systems using a single gas source, such optimized conditions may not be suitable for using two or more gas sources (e.g., growing GaN/InGaN stacked layer structures using both TMGa and TMIn). FIG. 6 depicts an embodiment of dual gas source vent/run piping system 600. Piping system 600 includes two first gas source 502A and second gas source 502B. In certain embodiments, first gas source 502A and second gas source 502B provide different source gases. For example, first gas source 502A may provide TMGa and second gas source 502B may provide TMIn. A drawback of piping system 600 is that flow controllers 510A, 510B control the flow of both source gases (e.g., TMGa and TMIn) after the source gases have been already combined into a single gas stream. Thus, there is no individual control of the source gases.

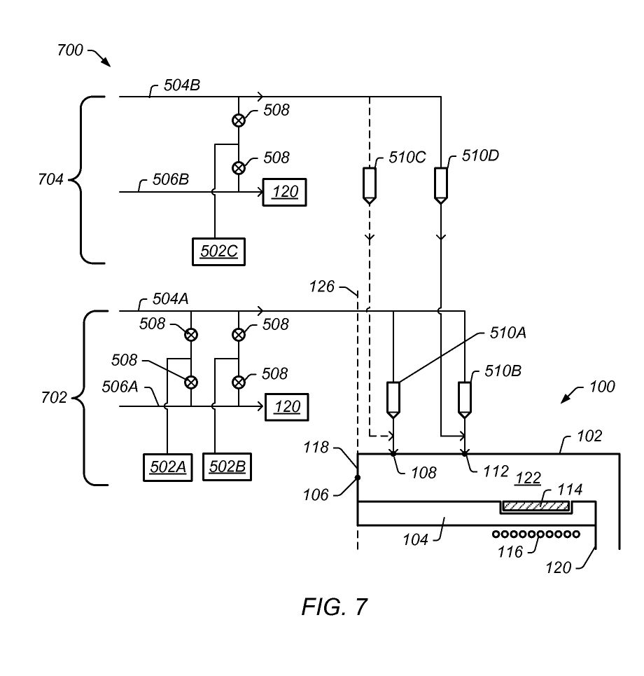

FIG. 7 depicts an embodiment of dual gas source vent/run piping system 700 with two piping branches 702, 704. Piping branch 702 includes first gas source 502A and second gas source 502B. Piping branch 704 includes third gas source 502C. In certain embodiments, third gas source 502C provides the same source gas as first gas source 502A (e.g., TMGa). In some embodiments, third gas source 502C provides the same source gas as first gas source 502B (e.g., TMIn).

As shown in FIG. 7, piping branch 702 includes flow controller 510A coupled to inlet 108 and flow controller 510B coupled to inlet 112. Thus, piping branch 702 provides combined gas streams from both first gas source 502A and second gas source 502B to inlets 108, 112 with a desired ratio between the inlets as determined by flow controllers 510A, 510B. For example, piping branch 702 may provide combined gas streams to inlets 108, 112 with substantially similar flow rates or with different flow rates.

In certain embodiments, piping branch 704 includes flow controller 510C coupled to inlet 108 and/or flow controller 510D coupled to inlet 112. For example, in one embodiment, piping branch 704 includes only flow controller 510C coupled to inlet 108. In another embodiment, piping branch 704 includes only flow controller 510D coupled to inlet 112. In yet another embodiment, piping branch 704 includes both flow controller 510C coupled to inlet 108 and flow controller 510D coupled to inlet 112. Thus, piping branch 704 may provide gas streams to inlets 108, 112 with a desired ratio between the inlets as determined by flow controllers 510C, 510D. For example, in some embodiments, piping branch 704 provides a gas stream to inlet 108 that has substantially the same flow rate as a gas stream provided to inlet 112 by the piping branch. In some embodiments, the flow rate of the gas stream provided to inlet 108 by piping branch 704 is different than the flow rate of the gas stream provided to inlet 112 from the piping branch. It is noted that, in certain embodiments, source gas flow from piping branch 704 is combined with source gas flow from piping branch 702 before the source gases are provided to inlet 108 and/or inlet 112.

The addition of source gas flow from third gas source 502C in piping branch 704 allows for control of the concentration in the source gas provided to inlet 108 and/or inlet 112. For example, if first gas source 502A provides TMGa, second gas source 502B provides TMIn, and third gas source 502C provides TMGa, adjustment of the amount of source gas provided from piping branch 704 (through flow controller 510C and/or flow controller 510D) adjusts the concentration of TMGa (and, thus, the concentration of TMIn in the source gas) provided to inlet 108 and/or inlet 112. Similarly, if third gas source 502C provides TMIn, adjustment of the amount of source gas provided from piping branch 704 adjusts the concentration of TMIn (and, thus, the concentration of TMGa in the source gas) provided to inlet 108 and/or inlet 112.

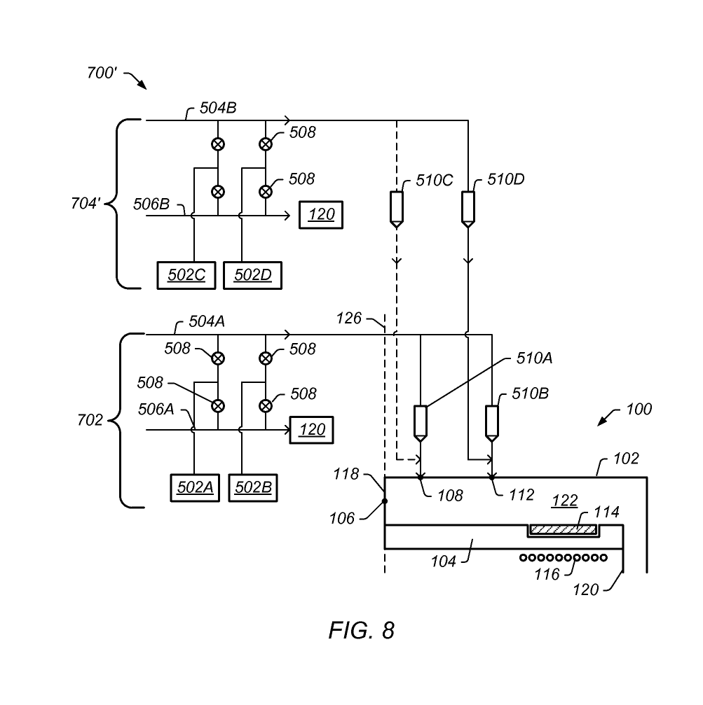

FIG. 8 depicts an alternative embodiment of dual gas source vent/run piping system 700′ with two piping branches 702, 704′. Piping branch 702 includes first gas source 502A and second gas source 502B. Piping branch 704′ includes third gas source 502C and fourth gas source 502D. In certain embodiments, third gas source 502C provides the same source gas as first gas source 502A (e.g., TMGa) and fourth gas source 502D provides the same source gas as second gas source 502B (e.g., TMIn).

As shown in FIG. 8, piping branch 702 includes flow controller 510A coupled to inlet 108 and flow controller 510B coupled to inlet 112. Thus, piping branch 702 provides combined gas streams from both first gas source 502A and second gas source 502B to inlets 108, 112 with a desired ratio between the inlets as determined by flow controllers 510A, 510B.

Piping branch 704′ may also provide combined gas streams from both first gas source 502A and second gas source 502B. In certain embodiments, piping branch 704′ includes flow controller 510C coupled to inlet 108 and/or flow controller 510D coupled to inlet 112. For example, in one embodiment, piping branch 704′ includes only flow controller 510C coupled to inlet 108. In another embodiment, piping branch 704′ includes only flow controller 510D coupled to inlet 112. In yet another embodiment, piping branch 704′ includes both flow controller 510C coupled to inlet 108 and flow controller 510D coupled to inlet 112. Thus, piping branch 704′ may provide combined gas streams from both first gas source 502A and second gas source 502B to inlets 108, 112 with a desired ratio between the inlets as determined by flow controllers 510C, 510D. For example, piping branch 704′ may provide combined gas streams to inlets 108, 112 with substantially similar flow rates or with different flow rates. In certain embodiments, source gas flow from piping branch 704′ is combined with source gas flow from piping branch 702 before the source gases are provided to inlet 108 and/or inlet 112.

Combining source gas flow from third gas source 502C and fourth gas source 502D in piping branch 704′ and source gas flow from first gas source 502A and second gas source 502B in piping branch 702 may provide more precise control of flow rates and/or concentrations in the source gases provided to inlet 108 and/or inlet 112. For example, in one embodiment, if both first gas source 502A and third gas source 502C provide TMGa and both second gas source 502B and fourth gas source 502D provide TMIn, piping branch 702 may provide a different ratio of TMGa/TMIn than piping branch 704′ such that adjustment of the gas flow rates from the different piping branches adjust the relative concentrations of TMGa and TMIn.

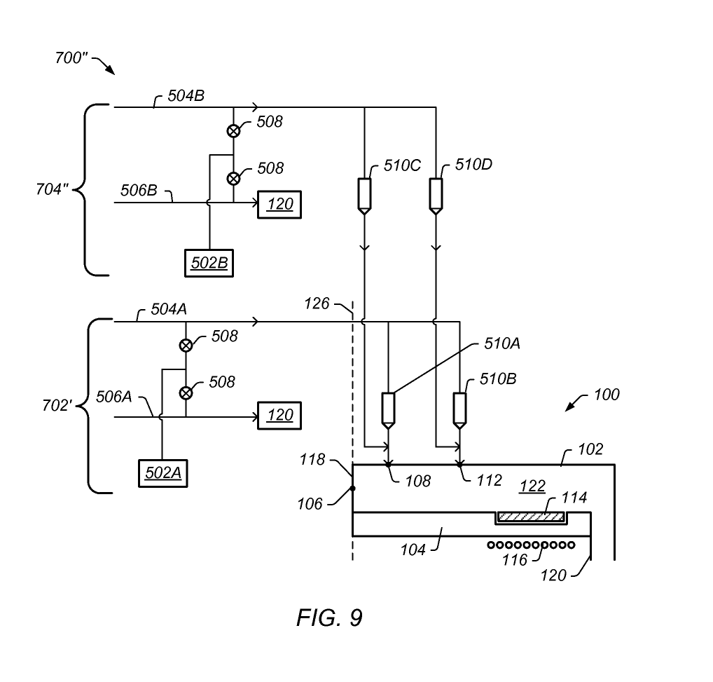

FIG. 9 depicts yet another embodiment of dual gas source vent/run piping system 700″ with two piping branches 702′, 704″. Piping branch 702′ includes first gas source 502A. Piping branch 704″ includes second gas source 502B. In certain embodiments, first gas source 502A provides a different source gas (e.g., TMGa) than second gas source 502B (e.g., TMIn).

As shown in FIG. 9, piping branch 702′ includes flow controller 510A coupled to inlet 108 and flow controller 510B coupled to inlet 112. Thus, piping branch 702′ provides gas streams from first gas source 502A to inlets 108, 112 with a desired ratio between the inlets as determined by flow controllers 510A, 510B. In certain embodiments, piping branch 704″ includes flow controller 510C coupled to inlet 108 and flow controller 510D coupled to inlet 112. Thus, piping branch 704″ provides gas streams from second gas source 502B to inlets 108, 112 with a desired ratio between the inlets as determined by flow controllers 510C, 510D. Piping branch 702′ and/or piping branch 704″ may provide gas streams to inlets 108, 112 with substantially similar flow rates or with different flow rates. In certain embodiments, source gas flow from piping branch 704″ is combined with source gas flow from piping branch 702′ before the source gases are provided to inlet 108 and/or inlet 112.

Combining single source gas flow from first gas source 502A in piping branch 702′ with single source gas flow from second gas source 502B in piping branch 704″ provides precise control of flow rates and/or concentrations in the source gases provided to inlet 108 and/or inlet 112. For example, in one embodiment, if first gas source 502A provides TMGa and second gas source 502B provides TMIn, precise control of flow rates of each source gas (TMGa or TMIn) may be provided by adjusting flow rates at each inlet 108, 112 with different flow controllers used for each gas at each inlet.

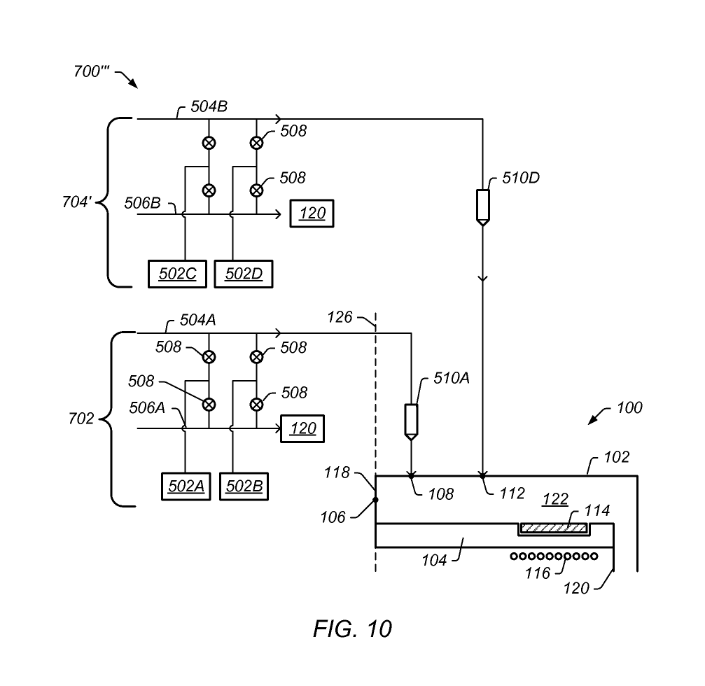

FIG. 10 depicts yet another alternative embodiment of a dual gas source vent/run piping system with two piping branches. The embodiment of piping system 700″′ depicted in FIG. 10 is similar to the embodiment of piping system 700′ depicted in FIG. 8 with both piping systems having two piping branches 702, 704′ with piping branch 702 including first gas source 502A and second gas source 502B and piping branch 704′ including third gas source 502C and fourth gas source 502D. Piping system 700″′, shown in FIG. 10, is different from piping system 700′, shown in FIG. 8, in that, in piping system 700″′, piping branch 702 includes only flow controller 510A and is only coupled to inlet 108 while piping branch 704′ includes only flow controller 510D and is only coupled to inlet 112. Thus, piping branch 702 provides combined gas streams from both first gas source 502A and second gas source 502B to inlet 108 and piping branch 704′ provides combined gas streams from both first gas source 502A and second gas source 502B to inlet 112.

Combining source gas flow from piping branch 702 with source gas flow from piping branch 704 (described in the embodiments depicted in FIGS. 7-10) provides control of flow rates and/or concentrations of multiple gas sources (e.g., TMGa, TEGa, TMAl, and/or TMIn) being provided to inlet 108 and/or inlet 112. Controlling the flow rates and/or concentrations of multiple gas sources allows a substantially uniform growth rate distribution to be provided in reaction chamber 122 (e.g., growth rates similar to curve 410 shown in FIG. 4) for films grown from the multiple source gases. For example, a concave growth rate distribution profile from one inlet (for example, inlet 108 such as shown by curve 402 in FIG. 4) may be combined with a convex growth rate distribution profile from another inlet (for example, inlet 112 such as shown by curve 404 in FIG. 4) to provide a substantially uniform growth rate distribution (e.g., a substantially flat growth rate distribution profile such as shown by curve 410 in FIG. 4). Thus, in certain embodiments, GaN, InGaN, and/or other desired films are grown with high uniformity with use of two or more piping branches such as piping branch 702 and piping branch 704.

GaN/InGaN films may be used in, for example, light emitting diodes (LEDs). GaN/InGaN films used in LEDs may need to be grown with high uniformity to provide reliable LEDs with desired properties. For example, there may be several GaN layers in the LED such that the uniformity of the GaN layers determines the total thickness distribution of the LED. Indium concentration may mainly be a factor in the active layer (e.g., a single quantum well layer or multiple quantum well layer) used in the LED (e.g., the light emitting layer). Higher indium concentrations in the active layer may produce LEDs with longer wavelengths. Thus, the uniformity of the indium concentration may determine the total wavelength distribution of the LED.

It is to be understood the invention is not limited to particular systems described which may, of course, vary. For example, as shown in FIGS. 7-10, inlet 108 may be replaced by a plurality of inlets and/or inlet 112 may be replaced by another plurality of inlets. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a component” includes a combination of two or more components and reference to “a material” includes mixtures of materials.

The present invention is directed to methods and systems of material fabrication. More particularly, the invention provides a rotation system and related method for forming epitaxial layers of semiconductor materials. Merely by way of example, the invention has been applied to metal-organic chemical vapor deposition, but it would be recognized that the invention has a much broader range of applicability.

In this patent, certain U.S. patents, U.S. patent applications, and other materials (e.g., articles) have been incorporated by reference. The text of such U.S. patents, U.S. patent applications, and other materials is, however, only incorporated by reference to the extent that no conflict exists between such text and the other statements and drawings set forth herein. In the event of such conflict, then any such conflicting text in such incorporated by reference U.S. patents, U.S. patent applications, and other materials is specifically not incorporated by reference in this patent.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A chemical vapor deposition system, comprising:
a gas injector;
one or more first inlets located in the gas injector;
one or more second inlets located in the gas injector;
a first piping branch coupled to the first inlets and/or the second inlets, wherein the first piping branch provides at least one gas to the first inlets and/or the second inlets during use, and wherein the first piping branch provides the at least one gas at a first flow rate to the first inlets and/or at a second flow rate to the second inlets; and
a second piping branch coupled to the first inlets and/or the second inlets, wherein the second piping branch provides at least one gas to the first inlets and/or the second inlets during use, and wherein the second piping branch provides the at least one gas at at least a third flow rate to the first inlets and/or the second inlets.

2. The system of claim 1, further comprising:
a susceptor configured to rotate around a central susceptor axis;
one or more substrate holders located on the susceptor, the substrate holders being configured to rotate around the central axis and around corresponding holder axes;
the gas injector comprising a central component and a plane component; and
one or more third inlets located in the central component.

3. The system of claim 2, wherein the one or more second inlets are located in the gas injector farther away from the central component than the one or more first inlets.

4. The system of claim 2, wherein the one or more first inlets and/or the one or more second inlets are located in the plane component.

5. The system of claim 2, wherein the one or more first inlets and/or the one or more second inlets are located in the central component.

6. The system of claim 2, wherein the third inlets provide one or more gases in a direction that is substantially parallel to a surface of the plane component.

7. The system of claim 2, wherein the first inlets and/or the second inlets provide gases in a direction that is substantially perpendicular to a surface of the plane component.

8. The system of claim 2, wherein the first inlets and/or the second inlets provide gases in a direction that is substantially parallel to a surface of the plane component.

9. The system of claim 1, wherein the first piping branch provides at least two gases, a first gas being different than a second gas.

10. The system of claim 1, wherein the first piping branch provides at least two gases, a first gas being different than a second gas, and wherein the at least one gas provided by the second piping branch is the same as either the first gas or the second gas provided by the first piping branch.

11. The system of claim 1, wherein the first piping branch provides one gas and the second piping branch provides one gas, and wherein the gas provided by the first piping branch is a different gas than the gas provided by the second piping branch.

12. The system of claim 1, wherein the first piping branch provides at least two gases and the second piping branch provides at least two gases, and wherein the at least two gases provided by the first piping branch are the same as the at least two gases provided by the second piping branch.

13. The system of claim 1, wherein the second piping branch provides at least two gases, a first gas being different than a second gas.

14. The system of claim 1, wherein at least one of the first piping branch or the second piping branch comprises a run line and a vent line, the run line providing the at least one gas to the first inlets and/or the second inlets, the vent line providing the at least one gas to an exhaust gas outlet, wherein the piping branch comprises one or more valves for switching flow of the at least one gas between the run line and the vent line during use.

15. The system of claim 1, wherein the at least one gas provided by the first piping branch and the at least one gas provided by the second piping branch comprise metal organic gas selected from a group consisting of trimethylgallium, triethylgallium, trimethylaluminum, and trimethylindium.

16. The system of claim 1, wherein the first inlets and/or the second inlets are positioned upstream of the one or more substrate holders.

17. The system of claim 1, wherein the first piping branch comprises at least one flow controller configured to control the first flow rate of the at least one gas and at least one flow controller configured to control the second flow rate of the at least one gas.

18. The system of claim 1, wherein the second piping branch comprises at least one flow controller configured to control the at least one third flow rate of the at least one gas.

19. The system of claim 1, wherein the second piping branch provides the at least one gas to the first inlets and the second inlets, and the third flow rate of the at least one gas at the first inlets is about the same as the third flow rate of the at least one gas at the second inlets.

20. The system of claim 1, wherein the second piping branch provides the at least one gas to the first inlets and the second inlets, and the third flow rate of the at least one gas at the first inlets is different from the third flow rate of the at least one gas at the second inlets.

21. A method for chemical vapor deposition, comprising:
providing a system for forming one or more layers of material on one or more substrates, the system comprising:
a gas injector;
one or more first inlets located in the gas injector; and
one or more second inlets located in the gas injector;
providing at least one gas, from a first piping branch, at a first flow rate to the first inlets and/or at a second flow rate to the second inlets; and
providing at least one additional gas, from a second piping branch, at at least a third flow rate to the first inlets and/or the second inlets.

22. The method of claim 21, wherein the system further comprises:
a susceptor configured to rotate around a central susceptor axis;
one or more substrate holders located on the susceptor, the substrate holders being configured to rotate around the central axis and around corresponding holder axes;
the gas injector comprising a central component and a plane component; and
one or more third inlets located in the central component.

23. The method of claim 22, wherein the one or more second inlets are located in the gas injector farther away from the central component than the one or more first inlets.

24. The method of claim 22, wherein the one or more first inlets and/or the one or more second inlets are located in the plane component.

25. The method of claim 22, wherein the one or more first inlets and/or the one or more second inlets are located in the central component.

26. The method of claim 21, further comprising providing at least two gases from the first piping branch, wherein a first gas is different than a second gas.

27. The method of claim 21, further comprising providing at least two gases from the first piping branch, wherein a first gas is different than a second gas, and wherein the at least one additional gas provided by the second piping branch is the same as either the first gas or the second gas provided by the first piping branch.

28. The method of claim 21, further comprising providing one gas from the first piping branch and one gas from the second piping branch, wherein the gas provided by the first piping branch is a different gas than the gas provided by the second piping branch.

29. The method of claim 21, further comprising providing at least two gases from the first piping branch and at least two gases from the second piping branch, wherein the at least two gases provided by the first piping branch are the same as the at least two gases provided by the second piping branch.

30. The method of claim 21, further comprising providing at least two gases from the second piping branch, wherein a first gas is different than a second gas.

31. The method of claim 21, further comprising combining the at least one gas from the first piping branch and the at least one additional gas from the second piping branch before providing the gases to the first inlets.

32. The method of claim 21, further comprising providing the at least one additional gas, from the second piping branch, to the first inlets and the second inlets at substantially similar flow rates.

33. The method of claim 21, further comprising providing the at least one additional gas, from the second piping branch, to the first inlets and the second inlets at different flow rates.

34. A chemical vapor deposition system for forming one or more layers of material on one or more substrates, comprising:
a gas injector;
one or more first inlets located in the gas injector;
one or more second inlets located in the gas injector; and
one or more piping branches coupled to the first inlets and the second inlets, wherein the one or more piping branches provide one or more gases, at a first flow rate to the first inlets and at a second flow rate to the second inlets;
wherein the first flow rate through the first inlets provides a concave growth rate distribution profile and the second flow rate through the second inlets provides a convex growth rate distribution profile, and wherein the concave growth rate distribution profile and the convex growth rate distribution profile are combined to provide a substantially uniform growth rate distribution profile for the one or more layers of material on the one or more substrates.

35. The system of claim 34, wherein a growth rate distribution profile comprises a growth rate distribution of the material as a function of location in the system.

36. The system of claim 34, wherein the one or more piping branches comprise at least one flow controller configured to control the first flow rate of the one or more gases and at least one flow controller configured to control the second flow rate of the one or more gases.
